(19) United States
(12) Patent Application Publication
(10) Pub. No.: US 2025/0209647 A1
(43) Pub. Date: Jun. 26, 2025

(54) K-DISTANCE TREE METROLOGY

(71) Applicant: FEI Company, Hillsboro, OR (US)

(72) Inventors: Spencer Forell, Beaverton, OR (US); John Flanagan, Hillsboro, OR (US)

(21) Appl. No.: 18/939,092

(22) Filed: Nov. 6, 2024

Related U.S. Application Data
(60) Provisional application No. 63/613,565, filed on Dec. 21, 2023.

(51) Int. Cl. G06T 7/50; G06T 7/00; G06T 7/73; G06V 10/26; G06V 10/44; G06V 10/82

(52) U.S. Cl. CPC G06T 7/50; G06T 7/0004; G06T 7/73; G06V 10/26; G06V 10/44; G06V 10/82; G06T 2207/20084; G06T 2207/30148

(57) ABSTRACT

Systems or techniques are provided for image metrology. In various embodiments, a system can comprise a memory that stores computer executable components and a processor that executes the computer executable components stored in the memory. The computer executable components can comprise a measurement component that accesses a k-distance data tree comprising positional coordinates of a plurality of shapes within an image; and measures distances between neighboring shapes of the plurality of shapes, wherein the measuring comprises parsing the k-distance data tree for nearest neighbor shapes within the plurality of shapes.

### CROSS-REFERENCE TO RELATED APPLICATIONS

This application claims priority to and the benefit of U.S. Provisional Application No. 63/613,565, entitled “METHOD FOR MEASURING NEAREST NEIGHBOR DISTANCE IN SEMICONDUCTOR DEVICES”, which was filed on Dec. 21, 2023.

The entirety of the aforementioned application is hereby incorporated herein by reference.

### BACKGROUND

Various technological fields utilize metrology as part of quality assurance processes. However, scaling of such metrology applications to large numbers of measurements can make such applications unfeasible.

### SUMMARY

The following presents a summary to provide a basic understanding of one or more embodiments. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatus or computer program products that facilitate nearest neighbor metrology using k-distance trees are provided.

According to one or more embodiments, a system is provided. The system can comprise a non-transitory computer-readable memory that can store computer-executable components. The system can further comprise a processor that can be operably coupled to the non-transitory computer-readable memory and that can execute the computer-executable components stored in the non-transitory computer-readable memory. In various embodiments, the computer-executable components can comprise a measurement component that accesses a k-distance data tree comprising positional coordinates of a plurality of shapes within an image; and measures distances between neighboring shapes of the plurality of shapes, wherein the measuring comprises parsing the k-distance data tree for nearest neighbor shapes within the plurality of shapes.

An advantage of the system, and/or of a corresponding computer-implemented method and/or computer program product can be improved performance when executing such nearest neighbor measurements across a large number of shapes within the image.

In one or more embodiments, the computer-executable components can further comprise a shape generation component that identifies one or more objects within the image; extracts contours of the one or more objects; and generates the one or more shapes based on the extracted contours.

An advantage of the system, and/or of a corresponding computer-implemented method and/or computer program product can be the ability to more accurately and efficiently determine measurements between nearest neighbor objects within the image.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a block diagram of an example scientific instrument module for performing metrology in accordance with various embodiments described herein.

FIG. 2 is a flow diagram of an example, non-limiting, method of performing metrology in accordance with various embodiments described herein.

FIGS. 3 and 4 illustrate block diagrams of example, non-limiting, scientific instruments that facilitate metrology in accordance with one or more embodiments described herein.

FIG. 5 illustrates an example of object identification in an image in accordance with one or more embodiments described herein.

FIG. 6 illustrates an example of contour extraction in an image in accordance with one or more embodiments described herein.

FIG. 7 illustrates an example of shape generation in an image in accordance with one or more embodiments described herein.

FIG. 8 illustrates an example of nearest neighbor measurement in accordance with one or more embodiments described herein.

FIG. 9 illustrates an example image with shapes and corresponding positional coordinates of said shapes in accordance with one or more embodiments described herein.

FIG. 10 illustrates an example of a kd data tree in accordance with one or more embodiments described herein.

FIG. 11 illustrates a flow diagram of an example, non-limiting computer-implemented method that can image metrology in accordance with one or more embodiments described herein.

FIG. 12 illustrates a flow diagram of an example, non-limiting, computer-implemented method that can facilitate shape generation for metrology in accordance with one or more embodiments described herein.

FIG. 13 illustrates a block diagram of an example, non-limiting, operating environment in which one or more embodiments described herein can be facilitated.

FIG. 14 illustrates an example of a charged particle microscope in accordance with one or more embodiments described herein.

### DETAILED DESCRIPTION

The following detailed description is merely illustrative and is not intended to limit embodiments and/or application or utilization of embodiments. Furthermore, there is no intention to be bound by any expressed or implied information presented in the preceding Summary section, or in the Detailed Description section. One or more embodiments are now described with reference to the drawings, wherein like reference numerals are utilized to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various technological fields call for the use of metrology as part of a quality assurance process. For example, in semiconductor manufacturing, the placement of various structures of the semiconductor, such as those found in NAND flash memory or dynamic random access memory cells is critical to proper performance. Accordingly, quality assurance processes for these types of devices rely on determining if the distances between the various structures meet the requirements of the specification. This is done through a nearest neighbor process, wherein distances are determined between nearest neighbor structures within the device being analyzed (such as a semiconductor). However, as the number of total structures increases, the computational resources needed to identify nearest neighbors increases as this is an O(N²) problem.

To overcome the one or more deficiencies of existing technologies as identified above, one or more embodiments described herein can access a k-distance (kd) data tree comprising positional coordinates of a plurality of shapes within an image and measuring distances between neighboring shapes of the plurality of shapes, wherein the measuring comprises parsing the kd tree for nearest neighbor shapes within the plurality of shapes. In one or more embodiments, the measuring can further comprise selecting a shape within the plurality of shapes, parsing the kd tree for a nearest neighbor shape to the selected shape, generating a line between a center point of the selected shape and a center point of the nearest neighbor shape, and determining a distance between a point where the line intersects an edge of the selected shape and a second point where the line intersects an edge of the nearest neighbor shape. By identifying the nearest neighbors through the use of the kd tree, the time to find the nearest neighbor can be reduced from O(N²) to O(log(n)).

Furthermore, one or more embodiments described herein can identify one or more objects within the image, extract contours of the one or more objects and generate the one or more shapes based on the extracted contours.

One or more embodiments are now described with reference to the drawings, where like referenced numerals are used to refer to like elements throughout. In the following description, for purposes of explanation, numerous specific details are set forth to provide a more thorough understanding of the one or more embodiments. It is evident in various cases, however, that the one or more embodiments can be practiced without these specific details.

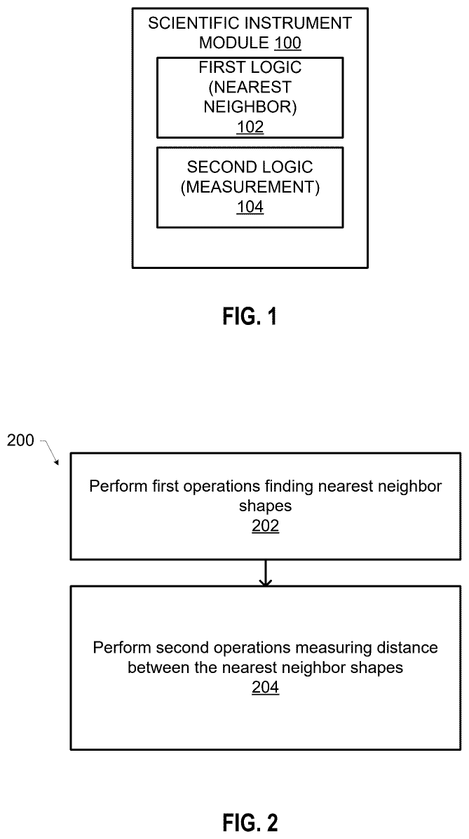

FIG. 1 illustrates an example, non-limiting block diagram of a scientific instrument module 100 in accordance with various embodiments described herein.

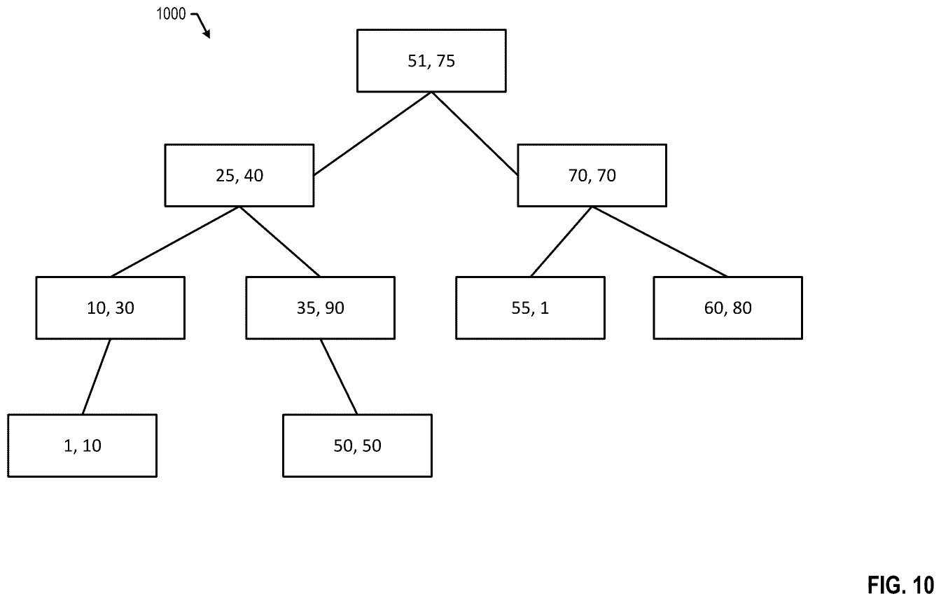

In various embodiments, the scientific instrument module 100 can be implemented by circuitry (e.g., including electrical or optical components), such as a programmed computing device. Logic of the scientific instrument module 100 can be included in a single computing device or can be distributed across multiple computing devices that are in communication with each other as appropriate. Examples of computing devices that may, singly or in combination, implement the scientific instrument module 100 are discussed herein with reference to FIG. 10.

The scientific instrument module 100 may include first logic 102 and second logic 104. As used herein, the term “logic” may include an apparatus that is to perform a set of operations associated with the logic elements. For example, any of the logic elements included in the scientific instrument module 100 may be implemented by one or more computing devices programmed with instructions to cause one or more processing devices of the computing devices to perform the associated set of operations. In a particular embodiment, a logic element may include one or more non-transitory computer-readable media having instructions thereon that, when executed by one or more processing devices of one or more computing devices, cause the one or more computing devices to perform the associated set of operations. As used herein, the term “module” may refer to a collection of one or more logic elements that, together, perform a function associated with the module. Different ones of the logic elements in a module may take the same form or may take different forms. For example, some logic in a module may be implemented by a programmed general-purpose processing device, while other logic in a module may be implemented by an application-specific integrated circuit (ASIC). In another example, different ones of the logic elements in a module may be associated with different sets of instructions executed by one or more processing devices. A module may not include all of the logic elements depicted in the associated drawing; for example, a module may include a subset of the logic elements depicted in the associated drawing when that module is to perform a subset of the operations discussed herein with reference to that module.

In various embodiments, there can be a scientific instrument corresponding to the scientific instrument module 100. In various aspects, the scientific instrument can be any suitable computerized device that can electronically measure some scientifically-relevant, clinically-relevant, or research-relevant characteristic, property, or attribute of an analytical sample (e.g., of a known or unknown mixture, compound, device or collection of matter).

The first logic 102 may parse a kd data tree comprising positional coordinates of a plurality of shapes within an image. For example, a starting shape can be selected from the plurality of shapes. The kd data tree can then be parsed to find positional coordinates nearest those of the selected shape. In one or more embodiments, multiple nearest neighbors can be identified if the positional coordinates are within a defined threshold of one and other.

The second logic 104 may measure distances between the nearest neighbors. For example, second logic 104 can generate a line between a center point of the selected shape and a center point of the nearest neighbor shape. Second logic 104 can then determine a distance between a point where the line intersects the edge of the selected shape and a second point where the line intersects an edge of the nearest neighbor shape based on the number of pixels of the image the line crosses. In an alternative embodiment, second logic 104 can measure the distance between the center point of the selected shape and the center point of the nearest neighbor shape. In the event that first logic 102 identifies multiple nearest neighbors, second logic 104 can measure the distance between the selected shape and each of the nearest neighbors.

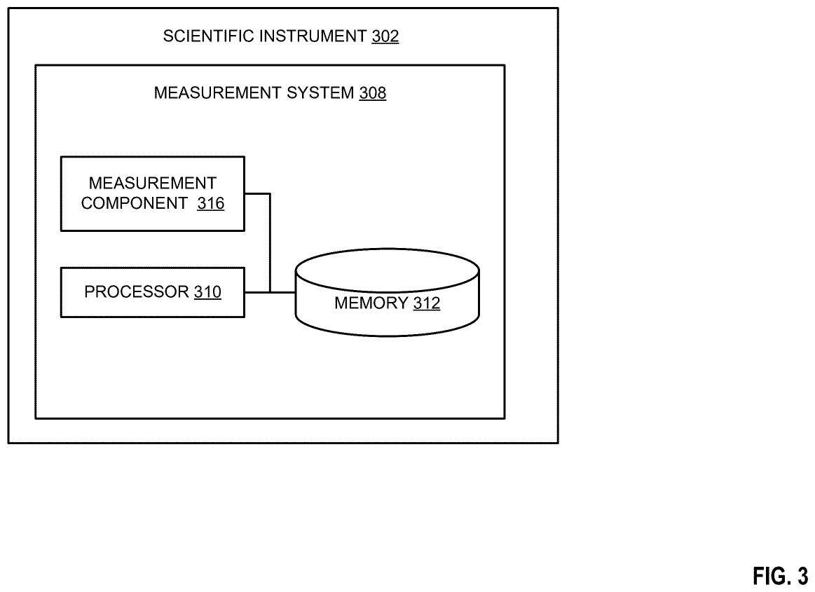

FIG. 2 is a flow diagram of a computer-implemented method 200 in accordance with one or more embodiments described herein. The operations of the computer-implemented method 200 may be used in any suitable setting to perform any suitable operations (e.g., can be performed by or used in conjunction with any of the various modules, computing devices, or graphical user interfaces described with respect to of FIGS. 1, 2, 11, 12 and 13). Operations are illustrated once each and in a particular order in FIG. 2, but the operations may be reordered or repeated as desired and appropriate (e.g., different operations performed may be performed in parallel, as suitable).

At 202, first operations may be performed. For example, the first logic 102 of scientific instrument module 100 may perform the operations of 202. The first operations may include identifying one or more nearest neighbor shapes to a selected shape within an image.

At 204, second operations may be performed. For example, the second logic 104 of scientific instrument module 100 may perform the operations of 204. The second operations may comprise measuring the distance between the selected shape and the one or more nearest neighbor shapes.

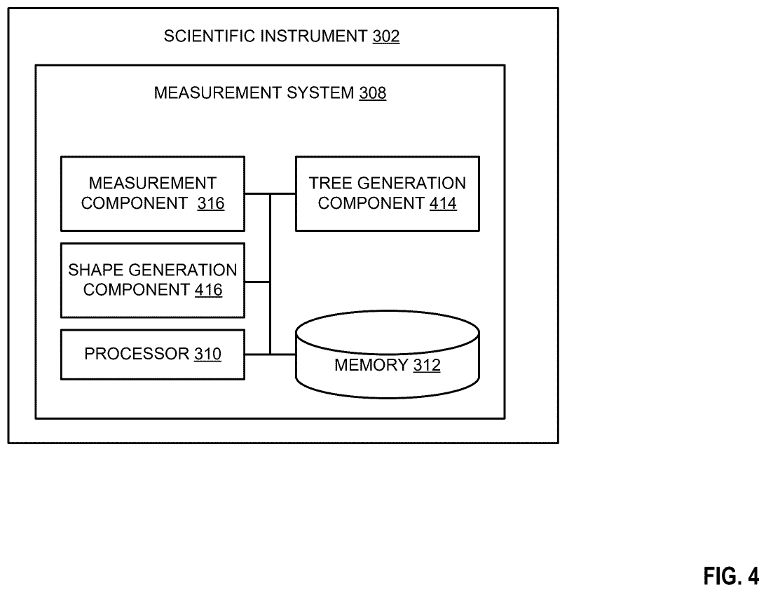

FIG. 3 illustrates a block diagram of an example, non-limiting scientific instrument that can facilitate metrology in accordance with one or more embodiments described herein.

In various embodiments, the scientific instrument 302 can comprise a measurement system 308. In various cases the measurement system 308 can facilitate metrology as part of a scientific analysis or quality assurance process.

In various aspects, the system 308 can comprise a processor 310 (e.g., computer processing unit, microprocessor) and a non-transitory computer-readable memory 312 that is operably or operatively or communicatively connected or coupled to the processor 310. The non-transitory computer-readable memory 312 can store computer-executable instructions which, upon execution by the processor 310, can cause the processor 310 or other components of the measurement system 308 (e.g., measurement component 316) to perform one or more acts. In various embodiments, the non-transitory computer-readable memory 312 can store computer-executable components (e.g., measurement component 316), and the processor 310 can execute the computer-executable components.

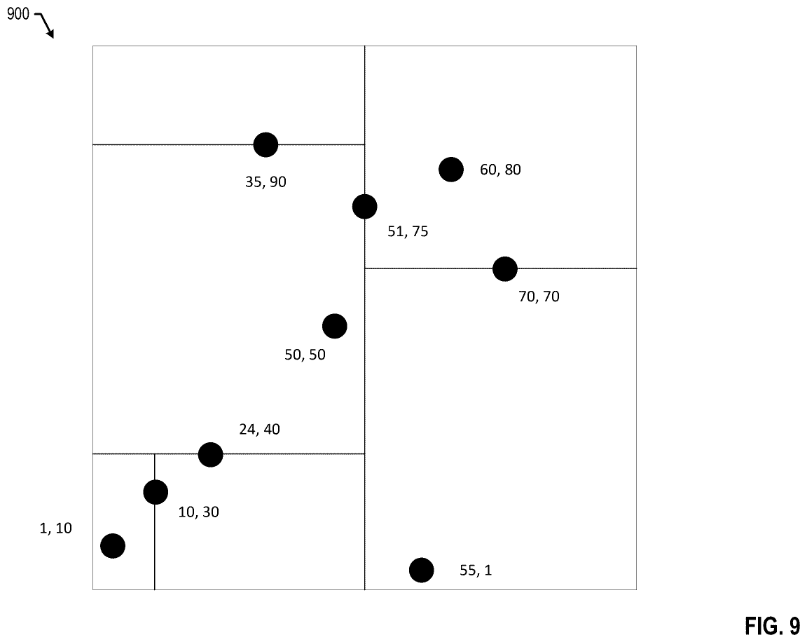

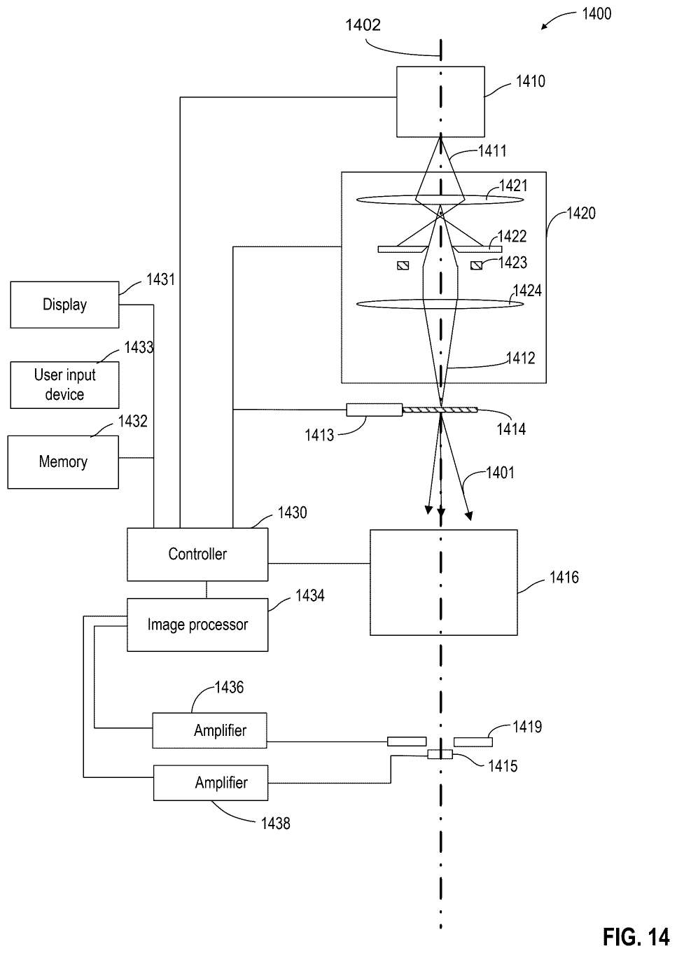

In various embodiments, measurement system 308 can comprise measurement component 316. In various aspects, measurement component 316 can measure the distances between various shapes within a plurality of images. For example, the plurality of shapes can represent a plurality of objects within the image, such as memory cells of a DRAM semiconductor device. Furthermore, positional coordinates of each shape of the plurality of shapes can be stored within a kd data tree. A kd tree is a form of binary tree structure, wherein nodes represent k-dimensional points. Non-leaf nodes of the tree split the tree into subtrees along hyperplanes, wherein the hyperplanes are perpendicular to that dimension's axis and alternate between dimensions. An example of a kd tree is discussed in greater detail below in reference to FIGS. 9 and 10. In various embodiments, scientific instrument 302 can further comprise or be communicatively coupled to a charge particle microscope that acquires the image for measurement. A non-limiting example of a charged particle microscope is described below in relation to FIG. 14.

Measurement component 316 can select a shape from the plurality of shapes in an image. Measurement component 316 can then parse the kd data tree to identify one or more nearest neighbor shapes to the selected shape based on a comparison of the positional coordinates of the plurality of shapes and the positional coordinates of the selected shape. For example, measurement component 316 can determine a difference between x-coordinates of the selected shape and another shape and the difference between the y-coordinates of the selected shape and another shape. These coordinate differences can then be added together to determine a positional difference between the selected shape and the other shape. Measurement component 316 can use this comparison for all nodes within the kd data tree to find a shape with the lowest coordinate difference. In some embodiments, measurement component 316 may identify multiple nearest neighbors to the selected shape. For example, multiple shapes may have the same coordinate difference to the selected shape. Alternatively, measurement component 316 can be selected to return x number of neighbors and can identify the x number of shapes with the lowest coordinate differences. Alternatively, measurement component 316 can return all shapes that are within a defined threshold of the lowest coordinate distance. For example, given a threshold of 4, measurement component 316 can identify the shape with the lowest coordinate difference to the selected shape and also include all shapes that a coordinate difference within 4 of the lowest coordinate difference.

In various embodiments, measurement component 316 can generate a line between a center point of the selected shape and a center point of the nearest neighbor shape. Measurement component 316 can then determine the distance between a point where the line intersects with an edge of the selected shape and a second point wherein the line intersects with an edge of the nearest neighbor shape. For example, the distance can be determined by the pixel length of the line. Alternatively, the distance can be determined based on the difference in coordinates between the first point and the second point. In an alternative embodiment, the distance can be measured between the center point of the selected shape and the center point of the nearest neighbor shape. In the event that multiple nearest neighbor shapes were identified, this process can be repeated to find the distance to each of the nearest neighbor shapes.

In various embodiments, measurement component 316 can compare the measured distances to a quality assurance specification. For example, if a manufacturing specification for a semiconductor device states that memory cells should be between x and y distance from neighboring memory cells, measurement component 316 can compare the measured distances to ensure that they are between x and y. If the measured distance is within this threshold, then the semiconductor can be approved. If the measured distance is less than or greater than this threshold, then the semiconductor device can be rejected.

FIG. 4 illustrates a block diagram of an example, non-limiting scientific instrument that can facilitate metrology in accordance with one or more embodiments described herein. As shown, scientific instrument 302 can comprise measurement system 308 as described above in relation to FIG. 3. Measurement system 308 of FIG. 4 can further comprise shape generation component 416 and tree generation component 414.

In various embodiments, shape generation component 416 can generate the plurality of shapes based on one or more objects within the image. For example, shape generation component 416 can identify one or more objects within the image. This identification can be achieved through the use of image segmentation, image processing machine learning models, such as neural networks, contrast comparison, or other methods for identification of portions of an image. Once an object has been identified, shape generation component 416 can extract the contours of the object based on a comparison of the contrast between object and the background of the image. Shape generation component 416 can then generate the plurality of shapes based on the extracted contours. For example, once an object has been identified and the contours extracted, shape generation component 416 can overlay a shape onto the image that matches or approximates the extracted contours. In one or more examples, these shapes can comprise circles, squares, ovals, ellipses and/or other shapes.

In various embodiments, tree generation component 414 can generate the k-distance data tree. For example, once shape component 416 has generated the plurality of shapes, tree generation component 414 can extract positional coordinates (e.g., x and y coordinates) for each shape's position in the image. Tree generation component 414 can then select starting positional coordinates from the plurality of positional coordinates corresponding to the plurality of shapes. In some embodiments, the starting positional coordinates can be selected as those closest to a specific portion of the image, such as center of the image, or a corner of the image. In another embodiment, the starting positional coordinates can be selected randomly. Once the starting positional coordinates are selected, tree generation component 414 can generate the kd data tree by generating subtrees based on alternating dimension hyperplanes between positional coordinates representing the plurality of shapes. An example of generation of the kd data tree is described in more detail below in reference to FIGS. 9 and 10.

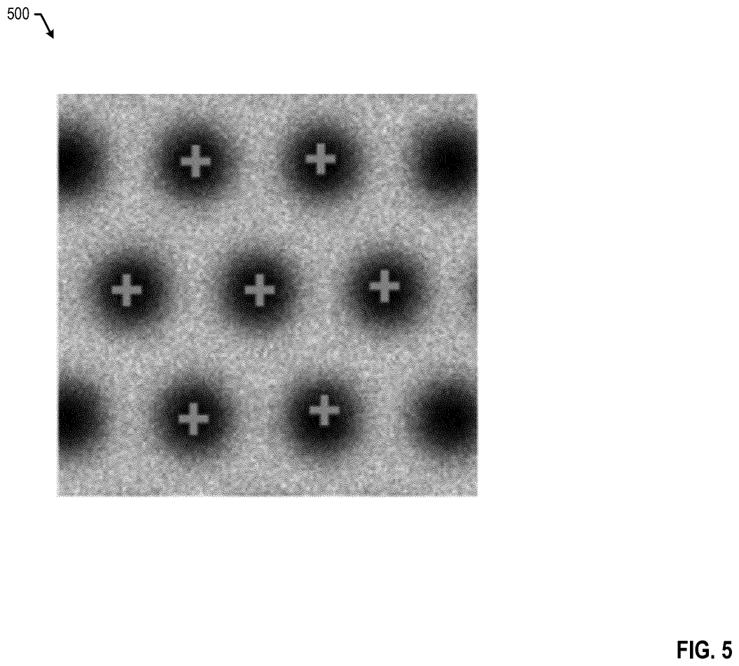

FIG. 5 illustrates an example of object identification in an image in accordance with one or more embodiments described herein.

Image 500 is of a direct random access memory (DRAM) semiconductor device. Such devices comprise a plurality of memory cells which must be appropriately spaced for optimal performance. As described above in reference to FIGS. 3 and 4, shape generation component 416 can identify one or more objects (memory cells in this example) within image 500 using a segmentation model, based on contrast comparison, or another image processing technique. Objects identified in image 500 are denoted by a cross icon.

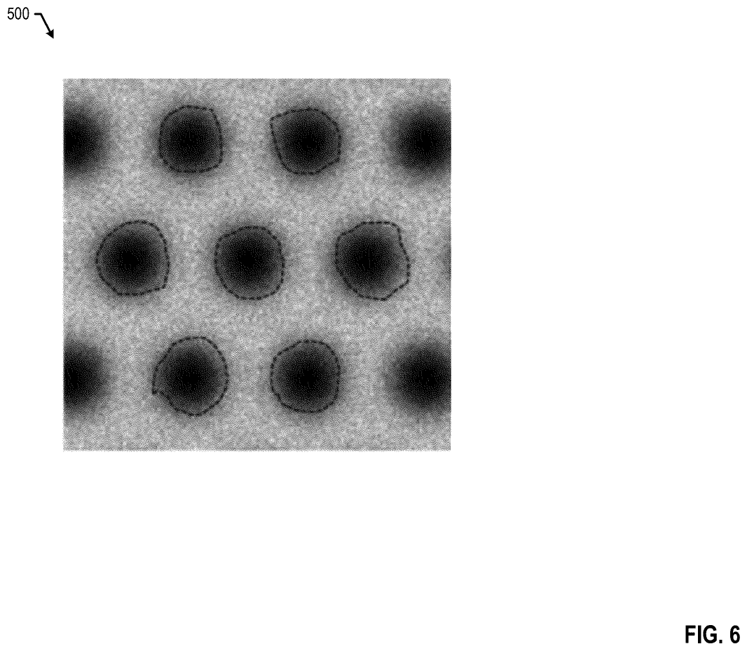

FIG. 6 illustrates an example of contour extraction in an image in accordance with one or more embodiments described herein.

As described above in reference to FIGS. 3 and 4, once objects have been identified, shape generation component 416 can then extract the contours of the objects based on a contrast comparison. As shown in image 500 in FIG. 6, the contours of the objects identified in FIG. 5 have been extracted.

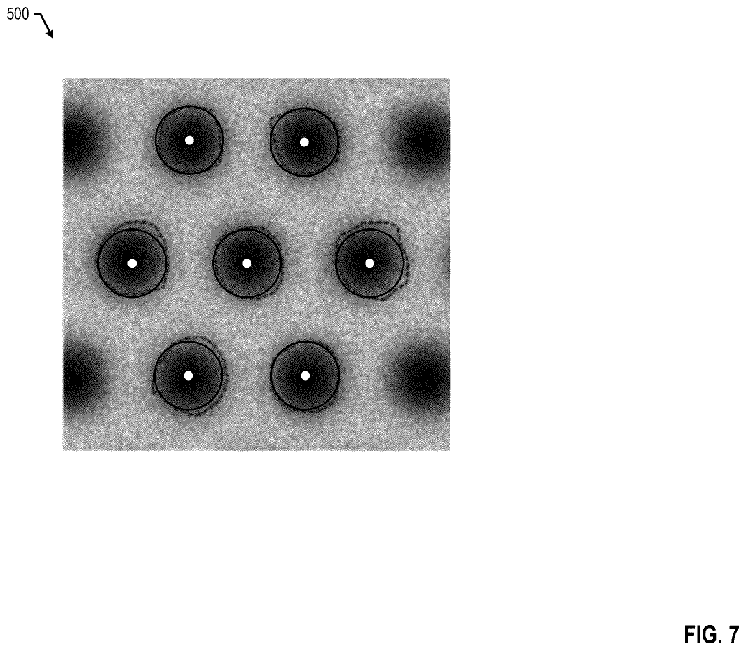

FIG. 7 illustrates an example of shape generation in an image in accordance with one or more embodiments described herein.

As described above in reference to FIGS. 3 and 4, once the contours of objects have been extracted, shape generation component 416 can then overlay shapes onto the extracted contours. This can be done in order to regularize the contours and make determining center points of the objects, as the center points of the shapes easier.

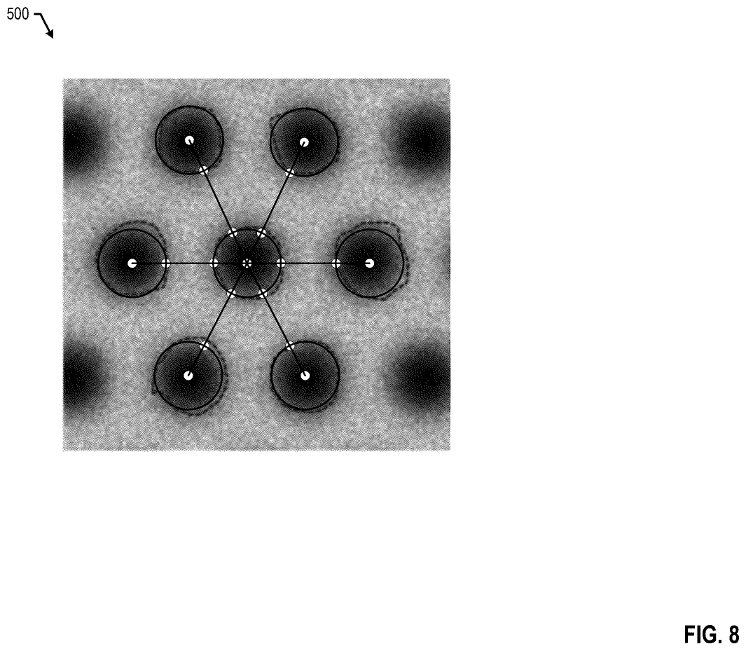

FIG. 8 illustrates an example of nearest neighbor measurement in accordance with one or more embodiments described herein.

As described above in reference to FIGS. 3 and 4, once the shapes have been overlayed onto the image, measurement component 316 can add a line between the center point of the selected shape and the center point of the nearest neighbor.

Measurement component 316 can then measure the distance from a point where the line intersects with the edge of the selected shape and a second point where the line intersects with the edge of the nearest neighbor shape. As shown in FIG. 8, corresponding lines have been drawn for each of the six nearest neighbor shapes surrounding the center selected shape.

FIGS. 9 and 10 illustrate an example of kd data tree generation in accordance with one or more embodiments described herein.

FIG. 9 illustrates an example image with shapes and corresponding positional coordinates of said shapes in accordance with one or more embodiments described herein. In one or more embodiments, tree generation component 414 can select a starting point at random, here it is (51,75). Tree generation component 414 can then select either a horizontal or vertical hyperplane. Here a vertical line through point (51, 75) has been added to represent the division of image 700 into a left half and a right half. Accordingly, all points on the left half of the line will be in a left sub-tree of point (51, 75) and all points on the right of the line will be in a right sub-tree of point (51, 75). Child nodes are then selected for point (51, 75), selected as (24, 40) and (70, 70) respectively. Alternating hyperplanes (e.g., horizontal lines) are then passed through points (24, 40) and (70, 70) respectively. This process of selecting points, generating hyperplanes and selecting child nodes based on the hyperplanes can then continue until all points have been added to the tree. An example of a kd tree built from image 900 is illustrated in FIG. 10.

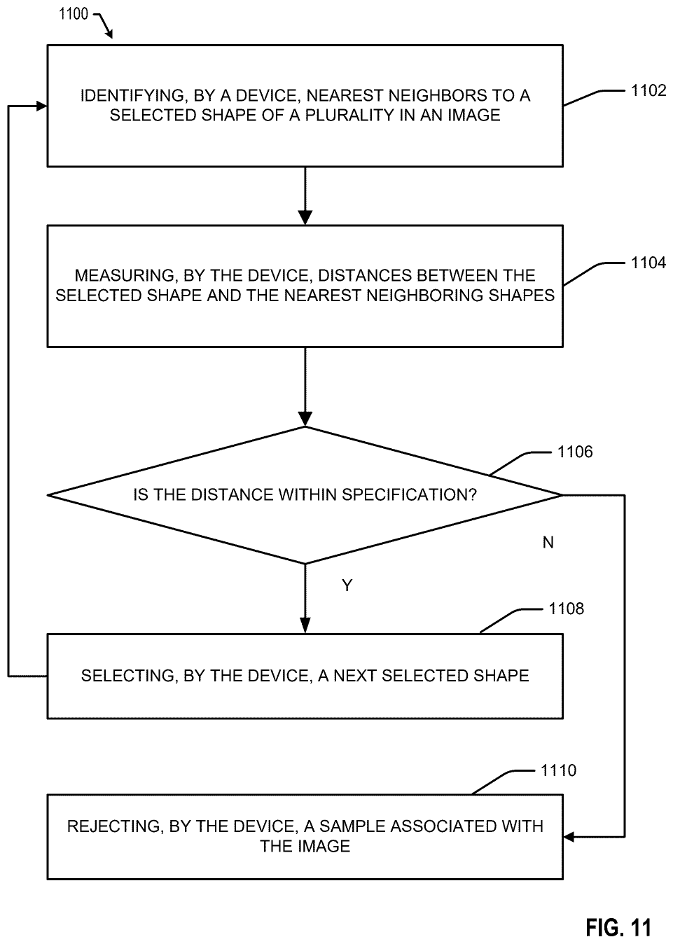

FIG. 11 illustrates a flow diagram of an example, non-limiting computer-implemented method 1100 that can perform image metrology in accordance with one or more embodiments described herein.

In various cases, measurement system 308 can facilitate the computer-implemented method 1100. In various embodiments, act 1102 can comprise, identifying, by a device (e.g., measurement component 316) nearest neighbor shapes to a selected shape of a plurality of shapes in an image. For example, as described above in relation to FIGS. 3-4, measurement component 316 can parse a kd data tree comprising positional coordinates of shapes within an image and identify one or more nearest neighbor shapes to a selected shape based on a comparison of the positional coordinates.

In various embodiments, act 1104 can comprise measuring, by the device (e.g., measurement component 316) distances between the nearest neighbor shapes and the selected shape. For example, as described above in relation to FIGS. 3-4, measurement component 316 can generate a line between a center point of the selected shape and a center point of a nearest neighbor shape. Measurement component 314 can then identify a first point where the line intersects the edge of the selected shape and a second point where the line intersects the edge of the nearest neighbor shape. Measurement component 314 can then determine the distance between the first point and the second point. Alternatively, measurement component 316 can measure the distance between the center point of the selected shape and the center point of the nearest neighbor shape. This measurement process can repeat for each of the nearest neighbor shapes identified.

In various embodiments, act 1106 can comprise determining, by the device (e.g., measurement component 316) if the measured distances are within a specification. For example, the specification may state that nearest neighbor distances must be between x and y distance. In response to a “YES” determination (e.g., all measured distances between the selected shape and the nearest neighbors are between x and y), method 1100 can proceed to act 1108 and select a next shape to measure nearest neighbor distances to. In response to a “NO” determination (e.g., one or more of the measured distances was less than x or greater than y), method 1100 can proceed to step 1110 and reject a sample associated with the image.

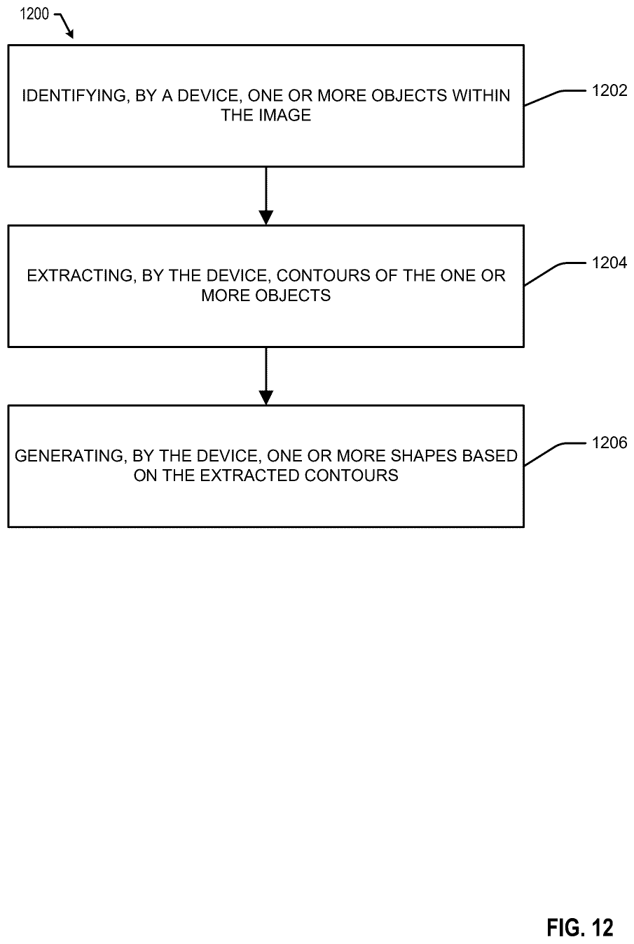

FIG. 12 illustrates a flow diagram of an example, non-limiting, computer-implemented method 1200 that can facilitate shape generation for metrology in accordance with one or more embodiments described herein.

In various embodiments, act 1202 can comprise identifying, by a device (e.g., shape generation component 416), one or more objects within an image. For example, given an image of a surface of a semiconductor device, shape generation component 416 can identify one or more objects within the image, such as memory cells of the semiconductor device, using an image segmentation model, a contrast comparison, and/or another image processing technique.

In various embodiments, act 1204 can comprise extracting, by the device (e.g., shape generation component 416), contours of the one or more objects. For example, shape generation component 416 can extract the contours of the one or more objects based on a contrast comparison of the object and the image background. Alternatively, shape generation component 416 can extract the contours based on the image segmentation of act 1202. In one or more embodiments, method 1200 can end at this point and measurement component 316 can measure distances using the extracted contours as the shapes.

In various embodiments, act 1206 can comprise generating, by the device (e.g., shape generation component 416) one or more shapes based on the extracted contours. For example, based on the extracted contours, shape generation component 416 can overlay one or more shapes that closely resemble the extracted contours to regularize the contours.

An advantage of the systems, and/or of corresponding computer-implemented methods and/or computer program products described herein can be the ability to scale more efficiently when measuring distances between a large number of shapes. For example, by storing the positional coordinates of the shapes of the image in a kd data tree, the search time for nearest neighbors is reduced to O (log (n). This drastically reduces the computational resources required to identify nearest neighbors and measure distances between nearest neighbors in images comprising a large number of objects.

In various instances, machine learning algorithms or models can be implemented in any suitable way to facilitate any suitable aspects described herein. To facilitate some of the above-described machine learning aspects of various embodiments, consider the following discussion of artificial intelligence (AI). Various embodiments described herein can employ artificial intelligence to facilitate automating one or more features or functionalities. The components can employ various Al-based schemes for carrying out various embodiments/examples disclosed herein. In order to provide for or aid in the numerous determinations (e.g., determine, ascertain, infer, calculate, predict, prognose, estimate, derive, forecast, detect, compute) described herein, components described herein can examine the entirety or a subset of the data to which it is granted access and can provide for reasoning about or determine states of the system or environment from a set of observations as captured via events or data. Determinations can be employed to identify a specific context or action, or can generate a probability distribution over states, for example. The determinations can be probabilistic; that is, the computation of a probability distribution over states of interest based on a consideration of data and events. Determinations can also refer to techniques employed for composing higher-level events from a set of events or data.

Such determinations can result in the construction of new events or actions from a set of observed events or stored event data, whether or not the events are correlated in close temporal proximity, and whether the events and data come from one or several event and data sources. Components disclosed herein can employ various classification (explicitly trained (e.g., via training data) as well as implicitly trained (e.g., via observing behavior, preferences, historical information, receiving extrinsic information, and so on)) schemes or systems (e.g., support vector machines, neural networks, expert systems, Bayesian belief networks, fuzzy logic, data fusion engines, and so on) in connection with performing automatic or determined action in connection with the claimed subject matter. Thus, classification schemes or systems can be used to automatically learn and perform a number of functions, actions, or determinations.

A classifier can map an input attribute vector, z=(z1, z2, z3, z4, zn), to a confidence that the input belongs to a class, as by f (z)=confidence (class). Such classification can employ a probabilistic or statistical-based analysis (e.g., factoring into the analysis utilities and costs) to determinate an action to be automatically performed. A support vector machine (SVM) can be an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, or probabilistic classification models providing different patterns of independence, any of which can be employed. Classification as used herein also is inclusive of statistical regression that is utilized to develop models of priority.

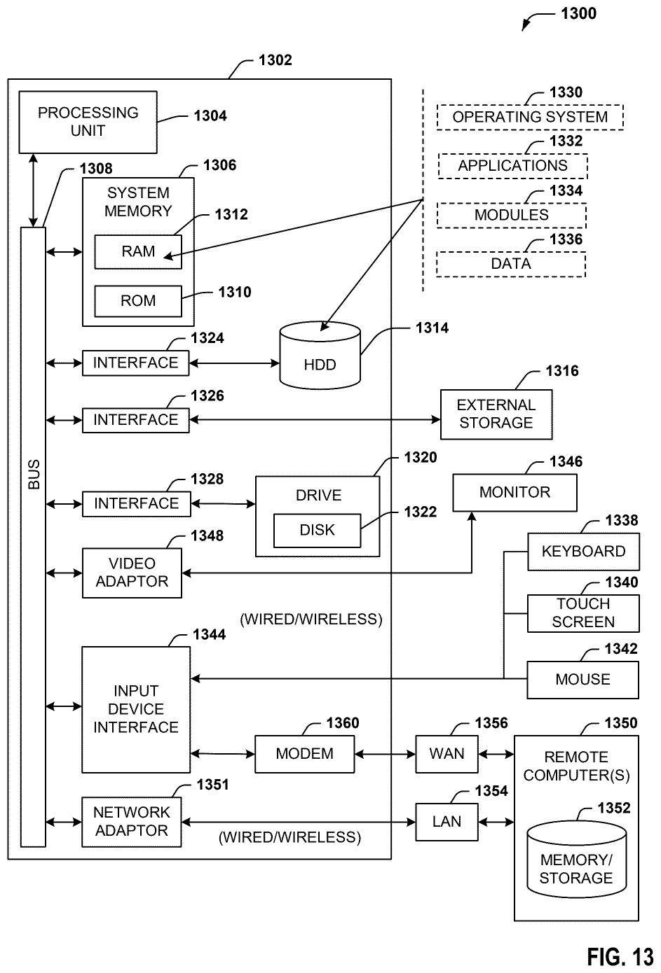

In order to provide additional context for various embodiments described herein, FIG. 13 and the following discussion are intended to provide a brief, general description of a suitable computing environment 1300 in which the various embodiments of the embodiment described herein can be implemented. While the embodiments have been described above in the general context of computer-executable instructions that can run on one or more computers, those skilled in the art will recognize that the embodiments can be also implemented in combination with other program modules or as a combination of hardware and software.

Generally, program modules include routines, programs, components, data structures, etc., that perform particular tasks or implement particular abstract data types. Moreover, those skilled in the art will appreciate that the inventive methods can be practiced with other computer system configurations, including single-processor or multi-processor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 13, the example environment 1300 for implementing various embodiments of the aspects described herein includes a computer 1302, the computer 1302 including a processing unit 1304, a system memory 1306 and a system bus 1308. The system bus 1308 couples system components including, but not limited to, the system memory 1306 to the processing unit 1304. The processing unit 1304 can be any of various commercially available processors. Dual microprocessors and other multi processor architectures can also be employed as the processing unit 1304.

The system bus 1308 can be any of several types of bus structure that can further interconnect to a memory bus (with or without a memory controller), a peripheral bus, and a local bus using any of a variety of commercially available bus architectures. The system memory 1306 includes ROM 1310 and RAM 1312. A basic input/output system (BIOS) can be stored in a non-volatile memory such as ROM, erasable programmable read only memory (EPROM), EEPROM, which BIOS contains the basic routines that help to transfer information between elements within the computer 1302, such as during startup. The RAM 1312 can also include a high-speed RAM such as static RAM for caching data.

The computer 1302 further includes an internal hard disk drive (HDD) 1314 (e.g., EIDE, SATA), one or more external storage devices 1316 (e.g., a magnetic floppy disk drive (FDD) 1316, a memory stick or flash drive reader, a memory card reader, etc.) and a drive 1320, e.g., such as a solid state drive, an optical disk drive, which can read or write from a disk 1322, such as a CD-ROM disc, a DVD, a BD, etc. Alternatively, where a solid state drive is involved, disk 1322 would not be included, unless separate. While the internal HDD 1314 is illustrated as located within the computer 1302, the internal HDD 1314 can also be configured for external use in a suitable chassis (not shown). Additionally, while not shown in environment 1300, a solid state drive (SSD) could be used in addition to, or in place of, an HDD 1314. The HDD 1314, external storage device(s) 1316 and drive 1320 can be connected to the system bus 1308 by an HDD interface 1324, an external storage interface 1326 and a drive interface 1328, respectively. The interface 1324 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 1302, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 1312, including an operating system 1330, one or more application programs 1332, other program modules 1334 and program data 1336. All or portions of the operating system, applications, modules, or data can also be cached in the RAM 1312. The systems and methods described herein can be implemented utilizing various commercially available operating systems or combinations of operating systems.

Computer 1302 can optionally comprise emulation technologies. For example, a hypervisor (not shown) or other intermediary can emulate a hardware environment for operating system 1330, and the emulated hardware can optionally be different from the hardware illustrated in FIG. 13. In such an embodiment, operating system 1330 can comprise one virtual machine (VM) of multiple VMs hosted at computer 1302. Furthermore, operating system 1330 can provide runtime environments, such as the Java runtime environment or the .NET framework, for applications 1332. Runtime environments are consistent execution environments that allow applications 1332 to run on any operating system that includes the runtime environment. Similarly, operating system 1330 can support containers, and applications 1332 can be in the form of containers, which are lightweight, standalone, executable packages of software that include, e.g., code, runtime, system tools, system libraries and settings for an application.

Further, computer 1302 can be enable with a security module, such as a trusted processing module (TPM). For instance with a TPM, boot components hash next in time boot components, and wait for a match of results to secured values, before loading a next boot component. This process can take place at any layer in the code execution stack of computer 1302, e.g., applied at the application execution level or at the operating system (OS) kernel level, thereby enabling security at any level of code execution.

A user can enter commands and information into the computer 1302 through one or more wired/wireless input devices, e.g., a keyboard 1338, a touch screen 1340, and a pointing device, such as a mouse 1342. Other input devices (not shown) can include a microphone, an infrared (IR) remote control, a radio frequency (RF) remote control, or other remote control, a joystick, a virtual reality controller or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 1304 through an input device interface 1344 that can be coupled to the system bus 1308, but can be connected by other interfaces, such as a parallel port, an IEEE 1394 serial port, a game port, a USB port, an IR interface, a BLUETOOTH® interface, etc.

A monitor 1346 or other type of display device can be also connected to the system bus 1308 via an interface, such as a video adapter 1348. In addition to the monitor 1346, a computer typically includes other peripheral output devices (not shown), such as speakers, printers, etc.

The computer 1302 can operate in a networked environment using logical connections via wired or wireless communications to one or more remote computers, such as a remote computer(s) 1350. The remote computer(s) 1350 can be a workstation, a server computer, a router, a personal computer, portable computer, microprocessor-based entertainment appliance, a peer device or other common network node, and typically includes many or all of the elements described relative to the computer 1302, although, for purposes of brevity, only a memory/storage device 1352 is illustrated. The logical connections depicted include wired/wireless connectivity to a local area network (LAN) 1354 or larger networks, e.g., a wide area network (WAN) 1356. Such LAN and WAN networking environments are commonplace in offices and companies, and facilitate enterprise-wide computer networks, such as intranets, all of which can connect to a global communications network, e.g., the Internet.

When used in a LAN networking environment, the computer 1302 can be connected to the local network 1354 through a wired or wireless communication network interface or adapter 1358. The adapter 1358 can facilitate wired or wireless communication to the LAN 1354, which can also include a wireless access point (AP) disposed thereon for communicating with the adapter 1358 in a wireless mode.

When used in a WAN networking environment, the computer 1302 can include a modem 1360 or can be connected to a communications server on the WAN 1356 via other means for establishing communications over the WAN 1356, such as by way of the Internet. The modem 1360, which can be internal or external and a wired or wireless device, can be connected to the system bus 1308 via the input device interface 1344. In a networked environment, program modules depicted relative to the computer 1302 or portions thereof, can be stored in the remote memory/storage device 1352. It will be appreciated that the network connections shown are example and other means of establishing a communications link between the computers can be used.

When used in either a LAN or WAN networking environment, the computer 1302 can access cloud storage systems or other network-based storage systems in addition to, or in place of, external storage devices 1316 as described above, such as but not limited to a network virtual machine providing one or more aspects of storage or processing of information. Generally, a connection between the computer 1302 and a cloud storage system can be established over a LAN 1354 or WAN 1356 e.g., by the adapter 1358 or modem 1360, respectively. Upon connecting the computer 1302 to an associated cloud storage system, the external storage interface 1326 can, with the aid of the adapter 1358 or modem 1360, manage storage provided by the cloud storage system as it would other types of external storage. For instance, the external storage interface 1326 can be configured to provide access to cloud storage sources as if those sources were physically connected to the computer 1302.

The computer 1302 can be operable to communicate with any wireless devices or entities operatively disposed in wireless communication, e.g., a printer, scanner, desktop or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a predefined structure as with a conventional network or simply an ad hoc communication between at least two devices.

FIG. 14 shows an example charged particle microscopy system 1400 in accordance with an embodiment of the disclosure is shown. For example, system 1400 may serve as an example of scientific instrument 302 of FIGS. 3 and 4. The charged particle microscopy system 1400 may be a scanning electron microscope (STEM). The STEM system 1400 includes an electron source 1410 that emits electron beam 1411 along an emission axis 1402, towards a focusing column 1420. In some embodiments, the focusing column 1420 may include one or more of a condenser lens 1421, aperture 1422, scan coils 1423, and upper objective lens 1424. The focusing column 1420 focuses electrons from electron source 1410 into a small spot on sample 1414. Different locations of the sample may be scanned by adjusting the electron beam direction via the scan coils 1423. For example, by operating scan coils 1423, incident beam 1412 may be shifted (as shown with dashed lines) to focus onto different locations of sample 1414. The sample 1414 may be thin enough to not impede transmission of most of the electrons in the electron beam 1411.

The sample 1414 may be held by a sample holder 1413. Electrons 1401 passing through sample 1414 may enter projector 1416. In one embodiment, the projector 1416 may be a separate part from the focusing column. In another embodiment, the projector 1416 may be an extension of the lens field from a lens in focusing column 1420. The projector 1416 may be adjusted by the controller 1430 so that direct electrons passed through the sample, impinge on disk-shaped bright field detector 1415, while diffracted or scattered electrons, which were more strongly deflected by the sample, are detected by the dark field detector 1419. Signals from the bright field and the dark field detectors may be amplified by amplifier 1438 and amplifier 1436, respectively. Signals from the amplifiers 1436 and 1438 may be sent to image processor 1434, which can form an image of sample 1414 from the detected electrons. In various embodiments, image processor 1434 can execute the metrology process (e.g., the functions of measurement component 316, tree generation component 414, and/or shape generation component 416) described above in relation to measurement system 308 of FIGS. 3 and 4. The STEM system 1400 may simultaneously detect signals from one or more of bright field detector and the dark field detector.

The controller 1430 may control the operation of the imaging system 1400, either manually in response to operator instructions or automatically in accordance with computer readable instructions stored in non-transitory memory 1432. The controller 1430 can be configured to execute the computer readable instructions and control various components of the imaging system 1400. For example, the controller may adjust the scanning location on the sample by operating the scan coils 1423. The controller may adjust the profile of the incident beam by adjusting one or more apertures and/or lens in the focusing column 1420. The controller may adjust the sample orientation relative to the incident beam by adjusting the sample holder 1413. The controller 1430 may further be coupled to a display 1431 to display notifications and/or images of the sample. The controller 1430 may receive user inputs from user input device 1433. The user input device 1433 may include keyboard, mouse, or touchscreen.

Though a STEM system is described by way of example, it should be understood that the electron source may also be used in other charged particle beam microscopy systems, such as transmitting electron microscopy (TEM) system, scanning electron microscopy (SEM) system, and dual beam microscopy system. The present discussion of STEM imaging is provided merely as an example of one suitable imaging modality and use of other imaging modalities is envisioned.

Various non-limiting aspects are described in the following examples.

EXAMPLE 1: A system comprising: a memory that stores computer executable components; and a processor that executes the computer executable components stored in the memory, wherein the computer executable components comprise: a measurement component that accesses a k-distance data tree comprising positional coordinates of a plurality of shapes within an image; and measures distances between neighboring shapes of the plurality of shapes, wherein the measuring comprises parsing the k-distance data tree for nearest neighbor shapes within the plurality of shapes.

EXAMPLE 2: The system of any preceding example, wherein the measurement component measures the distance by: selecting a shape within the plurality of shapes; parsing the k-distance tree for a nearest neighbor shape to the selected shape; generating a line between a center point of the selected shape and a center point of the nearest neighbor shape; and determining a distance between a point where the line intersects an edge of the selected shape and a second point where the line intersects an edge of the nearest neighbor shape.

EXAMPLE 3: The system of any preceding example, wherein the measurement component further measures the distance by determining the distance between a center point of the selected shape and a center point of the nearest neighbor shape.

EXAMPLE 4: The system of any preceding example, wherein the computer executable components further comprise a shape generation component that identifies one or more objects within the image; extracts contours of the one or more objects; and generates the one or more shapes based on the extracted contours.

EXAMPLE 5: The system of any preceding example, wherein the shape generation component comprises a segmentation neural network that identifies the one or more objects within the image.

EXAMPLE 6: The system of any preceding example, wherein the one or more objects comprise memory cells of a semiconductor device.

EXAMPLE 7: The system of any preceding example, wherein the computer executable components further comprise a tree generation component that generates the k-distance data tree, wherein the tree generation component generates the k-distance data tree by: converting the plurality of shapes into a plurality of positional coordinates; selecting starting positional coordinates from the plurality of positional coordinates; and generating one or more subtrees from the starting positional coordinates based on alternating dimension hyperplanes between positional coordinates of the plurality of positional coordinates.

In various aspects, any combination or combinations of EXAMPLES 1-7 can be implemented.

EXAMPLE 8: A computer-implemented method comprising: accessing, by a device operatively coupled to a processor, a k-distance data tree comprising positional coordinates of a plurality of shapes within an image; and measuring, by the device, distances between neighboring shapes of the plurality of shapes, wherein the measuring comprises parsing the k-distance data tree for nearest neighbor shapes within the plurality of shapes.

EXAMPLE 9: The computer-implemented method of any preceding example, wherein the measuring further comprises: selecting, by the device, a shape within the plurality of shapes; parsing, by the device, the k-distance tree for a nearest neighbor shape to the selected shape; generating, by the device, a line between a center point of the selected shape and a center point of the nearest neighbor shape; and determining, by the device, a distance between a point where the line intersects an edge of the selected shape and a second point where the line intersects an edge of the nearest neighbor shape.

EXAMPLE 10: The computer-implemented method of any preceding example, further comprising, determining, by the device, wherein the measuring further comprises determining, by the device the distance between a center point of the selected shape and a center point of the nearest neighbor shape.

EXAMPLE 11: The computer-implemented method of any preceding example, further comprising: identifying, by the device, one or more objects within the image; extracting, by the device, contours of the one or more objects; and generating, by the device, the one or more shapes based on the extracted contours.

EXAMPLE 12: The computer-implemented method of any preceding example, wherein the identifying comprises component a segmentation neural network identifying the one or more objects within the image.

EXAMPLE 13: The computer-implemented method of any preceding example, wherein the one or more objects comprise memory cells of a semiconductor device.

EXAMPLE 14: The computer-implemented method of any preceding example, further comprising generating the k-distance data tree, wherein the generating the k-distance data tree comprises: converting, by the device, the plurality of shapes into a plurality of positional coordinates; selecting, by the device, starting positional coordinates from the plurality of positional coordinates; and generating, by the device, one or more subtrees from the starting positional coordinates based on alternating dimension hyperplanes between positional coordinates of the plurality of positional coordinates.

In various aspects, any combination or combinations of EXAMPLES 8-14 can be implemented.

EXAMPLE 15: A computer program product comprising a non-transitory computer-readable memory having program instructions embodied therewith, the program instructions executable by a processor to cause the processor to: access, by the processor, a k-distance data tree comprising positional coordinates of a plurality of shapes within an image; and measure, by the processor, distances between neighboring shapes of the plurality of shapes, wherein the measuring comprises parsing the k-distance data tree for nearest neighbor shapes within the plurality of shapes.

EXAMPLE 16: The computer program product of any preceding example, wherein the measuring further comprises comprising: selecting, by the processor, a shape within the plurality of shapes; parsing, by the processor, the k-distance tree for a nearest neighbor shape to the selected shape; generating, by the processor, a line between a center point of the selected shape and a center point of the nearest neighbor shape; and determining, by the processor, a distance between a point where the line intersects an edge of the selected shape and a second point where the line intersects an edge of the nearest neighbor shape.

EXAMPLE 17: The computer program product of any preceding example, wherein the measuring further comprises determining, by the processor, the distance between a center point of the selected shape and a center point of the nearest neighbor shape.

EXAMPLE 18: The computer program product of any preceding example, wherein the program instructions are further executable by the processor, to cause the processor to: identify, by the processor, one or more objects within the image; extract, by the processor, contours of the one or more objects; and generate, by the processor, the one or more shapes based on the extracted contours.

EXAMPLE 19: The computer program product of any preceding example, wherein the identifying comprises component a segmentation neural network identifying the one or more objects within the image.

EXAMPLE 20: The computer program product of any preceding example, wherein the one or more objects comprise memory cells of a semiconductor device.

In various aspects, any combination or combinations of EXAMPLES 15-20 can be implemented.

In various aspects, any combination or combinations of EXAMPLES 1-20 can be implemented.

What is claimed is:

1. A system comprising:
a memory that stores computer executable components; and
a processor that executes the computer executable components stored in the memory, wherein the computer executable components comprise:
a measurement component that accesses a k-distance data tree comprising positional coordinates of a plurality of shapes within an image; and
measures distances between neighboring shapes of the plurality of shapes, wherein the measuring comprises parsing the k-distance data tree for nearest neighbor shapes within the plurality of shapes.

2. The system of claim 1, wherein the measurement component measures the distances by:
selecting a shape within the plurality of shapes;
parsing the k-distance data tree for a nearest neighbor shape to the selected shape;
generating a line between a center point of the selected shape and a center point of the nearest neighbor shape; and
determining a distance between a point where the line intersects an edge of the selected shape and a second point where the line intersects an edge of the nearest neighbor shape.

3. The system of claim 2, wherein the measurement component further measures the distance by determining the distance between a center point of the selected shape and a center point of the nearest neighbor shape.

4. The system of claim 1, wherein the computer executable components further comprise a shape generation component that identifies one or more objects within the image; extracts contours of the one or more objects; and generates the one or more shapes based on the extracted contours.

5. The system of claim 4, wherein the shape generation component comprises a segmentation neural network that identifies the one or more objects within the image.

6. The system of claim 4, wherein the one or more objects comprise memory cells of a semiconductor device.

7. The system of claim 1, wherein the computer executable components further comprise a tree generation component that generates the k-distance data tree, wherein the tree generation component generates the k-distance data tree by:
converting the plurality of shapes into a plurality of positional coordinates;
selecting starting positional coordinates from the plurality of positional coordinates; and
generating one or more subtrees from the starting positional coordinates based on alternating dimension hyperplanes between positional coordinates of the plurality of positional coordinates.

8. A computer-implemented method comprising:
accessing, by a device operatively coupled to a processor, a k-distance data tree comprising positional coordinates of a plurality of shapes within an image; and
measuring, by the device, distances between neighboring shapes of the plurality of shapes, wherein the measuring comprises parsing the k-distance data tree for nearest neighbor shapes within the plurality of shapes.

9. The computer-implemented method of claim 8, wherein the measuring further comprises:
selecting, by the device, a shape within the plurality of shapes;
parsing, by the device, the k-distance data tree for a nearest neighbor shape to the selected shape;
generating, by the device, a line between a center point of the selected shape and a center point of the nearest neighbor shape; and
determining, by the device, a distance between a point where the line intersects an edge of the selected shape and a second point where the line intersects an edge of the nearest neighbor shape.

10. The computer-implemented method of claim 9, wherein the measuring further comprises determining, by the device the distance between a center point of the selected shape and a center point of the nearest neighbor shape.

11. The computer-implemented method of claim 9, further comprising:
identifying, by the device, one or more objects within the image;
extracting, by the device, contours of the one or more objects; and
generating, by the device, the one or more shapes based on the extracted contours.

12. The computer-implemented method of claim 11, wherein the identifying comprises component a segmentation neural network identifying the one or more objects within the image.

13. The computer-implemented method of claim 11, wherein the one or more objects comprise memory cells of a semiconductor device.

14. The computer-implemented method of claim 8, further comprising generating the k-distance data tree, wherein the generating the k-distance data tree comprises:
converting, by the device, the plurality of shapes into a plurality of positional coordinates;
selecting, by the device, starting positional coordinates from the plurality of positional coordinates; and
generating, by the device, one or more subtrees from the starting positional coordinates based on alternating dimension hyperplanes between positional coordinates of the plurality of positional coordinates.

15. A computer program product comprising a non-transitory computer-readable memory having program instruction embodied therewith, the program instructions executable by a processor to cause the processor to:
access, by the processor, a k-distance data tree comprising positional coordinates of a plurality of shapes within an image; and
measure, by the processor, distances between neighboring shapes of the plurality of shapes, wherein the measuring comprises parsing the k-distance data tree for nearest neighbor shapes within the plurality of shapes.

16. The computer program product of claim 15, wherein the measuring further comprises comprising:
selecting, by the processor, a shape within the plurality of shapes;
parsing, by the processor, the k-distance data tree for a nearest neighbor shape to the selected shape;
generating, by the processor, a line between a center point of the selected shape and a center point of the nearest neighbor shape; and
determining, by the processor, a distance between a point where the line intersects an edge of the selected shape and a second point where the line intersects an edge of the nearest neighbor shape.

17. The computer program product of claim 16, wherein the measuring further comprises determining, by the processor, distance between a center point of the selected shape and a center point of the nearest neighbor shape.

18. The computer program product of claim 15, wherein the program instructions are further executable by the processor to cause the processor to:
identify, by the processor, one or more objects within the image;
extract, by the processor, contours of the one or more objects; and
generate, by the processor, the one or more shapes based on the extracted contours.

19. The computer program product of claim 18, wherein the identifying comprises component a segmentation neural network identifying the one or more objects within the image.

20. The computer program product of claim 18, wherein the one or more objects comprise memory cells of a semiconductor device.
